(19) United States
(12) Patent Application Publication
(10) Pub. No.: US 2011/0201159 A1
(43) Pub. Date: Aug. 18, 2011

(54) SEMICONDUCTOR PACKAGE AND MANUFACTURING METHOD THEREOF

(75) Inventors: Shuji Mori, Fukuoka (JP); Koji Shimizu, Fukuoka (JP); Nozomi Nishimura, Fukuoka (JP)

(73) Assignee: MITSUI HIGH-TEC, INC., Kitakyushu-shi, Fukuoka (JP)

(21) Appl. No.: 13/123,385

(22) PCT Filed: Sep. 25, 2009
(86) PCT No.: PCT/JP2009/066659

§ 371 Date: Apr. 8, 2011

(30) Foreign Application Priority Data
Nov. 5, 2008 (JP) 2008-284531

(51) Int. Cl. H01L 21/60

(52) U.S. Cl. 438/123; 257/E21.506

(57) ABSTRACT

A semiconductor package 10 comprising: terminals 14 electrically connected to a semiconductor device 11; and a resin 15 for sealing a part of the terminals 14 and the device 11; wherein an electrolytic plating layer 19 of Ag, Sn, or Ni is formed on each of bottom surfaces 17 of the terminals 14 partly projecting from the resin 15; an electroless plating layer 22 of Ni, Sn, Ag, Ag/Au, Ni/Au, Ni/Ag, Ni/Pd/Au, or Ni/Pd/Ag is formed thereon; and an electroless plating layer 22 comprising the same material as the electroless plating layer 22 previously formed on the bottom surface 17 of the protruding terminal 14, is formed on each lateral surfaces 20 of the protruding terminals 14. This configuration enables a lead frame material 32 to be etched from its bottom surface to separate the terminals 14 from each other, thereby preventing corrosion due to oxidation of the lateral surfaces (standoff sides) of the terminals 14 exposed by the etching, and further reducing a total manufacturing cost.

### TECHNICAL FIELD

The present invention relates to a semiconductor package and a manufacturing method thereof, and in particular, to a semiconductor package to be mounted on a board with increased reliability and a manufacturing method thereof.

### BACKGROUND ART

In a semiconductor package including an IC (Integrated Circuit) chip and terminals projecting from a bottom surface of a sealing resin, a distance from the bottom surface of the sealing resin to a surface of a mounting board is referred to as “standoff (stand-off)” (see FIG. 4 (c)). And, the package needs to have an appropriate standoff to ensure reliability and ease of mounting. Patent Document 1 discloses a manufacturing method of a semiconductor package with such standoff structure. According to the disclosure of Patent Document 1, the conventional semiconductor package with the standoff structure will be briefly outlined with reference to FIG. 4.

As shown in FIG. 4 (a), selective etching (first etching) is performed on a plate-like lead frame material 70 from its surface down to approximately half the thickness of the same, such that areas to form bonding terminals 71 and as such are left unetched. As shown in FIG. 4 (b), a semiconductor device is mounted (bonded) on the lead frame material 70 and wire-bonding is performed using bonding wires 72, and then an approximate upper half of the lead frame material 70 is sealed with a resin 73. As shown in FIG. 4 (c), selective etching (second etching) is performed on the lead frame material 70 from its bottom surface, thereby separating the adjacent terminals 71 from each other. As shown in FIG. 4 (d), the semiconductor package is mounted on a board 75 etc.

Since mounted on the board in a nitrogen gas (or other inert gas) atmosphere, the semiconductor package manufactured in this way can maintain solderability of a lateral surface of the terminal 71 exposed by the second etching. Therefore, the semiconductor package can be mounted on the board with high reliability. A numeral 76 indicates solder.

As etching solutions for the lead frame material made of copper, for example, Patent Document 2 discloses a ferric chloride solution and an alkali etching solution containing copper tetramine chloride.

### PRIOR ART DOCUMENTS

### Patent Document

[Patent Document 1] Japanese Unexamined Patent Application Publication No. 2001-24135

[Patent Document 2] Japanese Unexamined Patent Application Publication No. 2005-353622

### SUMMARY OF INVENTION

### Problems to be Solved by the Invention

The lead frame material such as copper is exposed on the lateral surface of the standoff terminal by the second etching, and this exposed surface may be, for example, oxidized or contaminated before the semiconductor package is mounted on the board.

If the exposed surface of the terminal is oxidized or contaminated, an oxide film is formed thereon during mounting, which degrades the solderability and the reliability of mounting. As countermeasures, the semiconductor package has to be mounted on the board in the inert gas atmosphere, or the amount of solder has to be adjusted to make the solder rise up to a required level.

However, these countermeasures cause problems. In particular, the inert gas is expensive, and it is difficult to control the amount of solder so as to stably secure the solder wettability of the exposed surface of the terminal.

As another countermeasure, the lateral surface of the terminal may be plated. In this case, however, electric current cannot be applied to the terminal since the terminal is connected to the semiconductor device. For this reason, nickel or gold may be plated on the lateral surface of the terminal by an electroless plating method, thereby ensuring the solderability. However, the electroless nickel plating may cause corrosion, thus the solderability cannot be improved sufficiently.

In addition, the electroless gold plating is expensive because of increased usage of gold.

In view of the above circumstances, an object of the present invention is to provide a semiconductor package and a manufacturing method thereof, preventing corrosion due to oxidation etc. of lateral surfaces (standoff sides) of terminals which are exposed by etching a lead frame material from its bottom surface and separating the terminals from each other. Further, the semiconductor package and the manufacturing method thereof can reduce a total cost of production.

### MEANS FOR SOLVING PROBLEMS

To accomplish the above object, a first aspect of the present invention provides a semiconductor package comprising: a semiconductor device; terminals electrically connected to the semiconductor device; and a resin for sealing a part of the terminals and the semiconductor device, wherein bottom surfaces of (a) the terminals or (b) the terminals and a die pad, partly projecting from the resin, are each plated with an electrolytic plating layer comprising Ag, Sn, Ni, Ni/Au, Ni/Ag, Ni/Pd/Au, or Au; the electrolytic plating layers are each plated with at least one electroless plating layer; and lateral surfaces of (a) the terminals or (b) the terminals and the die pad, partly projecting from the resin, are each plated with an electroless plating layer comprising the same material as the electroless plating layer previously formed on the bottom surface of the terminal.

The expression “Ni/Ag” means that an Ag plate is formed over an Ni plate, and “Ni/Pd/Au” means that a Pd plate is formed over an Ni plate, and an Au plate is formed further over the Pd plate. (Hereinafter, expressions using “/(slash)” mean the same.)

Second and third aspects of the present invention provide a semiconductor package according to the first aspect, wherein the electrolytic plating layer is formed by a layer of Ag, Sn, or Ni; and the electroless plating layer is formed by a layer of Ni, Sn, Ag, Ag/Au, Ni/Au, Ni/Ag, Ni/Pd/Au, or Ni/Pd/Ag.

A fourth aspect of the present invention provides a semiconductor package according to the first aspect, wherein the electrolytic plating layer is formed by a layer of Ni/Ag, Ni/Pd/Au, or Au; and the electroless plating layer is formed by a layer of Sn, Ag, Ni/Au, Ni/Ag, Ni/Pd/Au, or Ni/Pd/Ag.

A fifth aspect of the present invention provides a semiconductor package according to the first to fourth aspects, wherein outermost layers of the bottom and lateral surfaces of (a) the projecting terminals or (b) the projecting terminals and the projecting die pad are each coated with an organic film which do not interfere with solder joint with a board.

Preferably, the organic film can be removed by cleaning with chemicals before the organic film is joined (connected) to the board, and also can be vaporized by heat during soldering. (The same is applied to a ninth aspect of the present invention.)

A sixth aspect of the present invention provides a manufacturing method of a semiconductor package comprising a first step of forming a first circuit pattern and a second circuit pattern respectively on an upper surface and a lower surface of a lead frame material, the first and second circuit patterns forming (a) terminals, or (b) terminals and a die pad; a second step of forming a first plating layer and a second plating layer respectively on the upper surface and the lower surface of the lead frame material; a third step of half-etching the lead frame material from the upper surface using the first plating layer as a resist film; a fourth step of mounting a semiconductor device on the die pad in the upper surface, bonding wires, and then sealing the device with a resin to fabricate an interim product; and a fifth step of half-etching the interim product with an alkali etching solution using the second plating layer as a resist film, thereby separating the terminals from each other, wherein the second plating layer in the second step is formed by an electroplating method (layer); and the fifth step is followed by a sixth step of forming at least one electroless plating layer on each of the lateral and bottom surfaces of (a) the terminals or (b) the terminals and the die pad, projecting from the resin.

In this regard, the interim product in the fourth step is manufactured by (a) mounting the semiconductor device on the lead frame material, which has the projecting terminal electrically connected to each other, (b) bonding wires, and (c) sealing the device with the resin. Also, the alkali etching solution dissolves the lead frame material (usually made of copper or copper alloy), but does not dissolve Ni, Sn, Ag, etc. For example, copper tetramine chloride is one of the alkali etching solutions.

A seventh aspect of the present invention provides a manufacturing method of a semiconductor package according to the sixth aspect, wherein the electrolytic plating layer is formed by a layer of Ag, Sn, or Ni; and the electroless plating layer is formed by a layer of Ni, Sn, Ag, Ag/Au, Ni/Au, Ni/Ag, Ni/Pd/Au, or Ni/Pd/Ag.

An eighth aspect of the present invention provides a manufacturing method of a semiconductor package according to the sixth aspect, wherein the electrolytic plating layer is formed by a layer of Ni/Ag, Ni/Pd/Au, or Au; and the electroless plating layer is formed by a layer of Sn, Ag, Ni/Au, Ni/Ag, Ni/Pd/Au, or Ni/Pd/Ag.

A ninth aspect of the present invention provides a manufacturing method of a semiconductor package according to the sixth to eighth aspects, wherein uppermost layers of (a) the terminals or (b) the terminals and the die pad, projecting from the resin, are each coated with an organic film which do not interfere with solder joint with a board.

In the present invention, Cu indicates copper or copper alloy, Ni indicates nickel or nickel alloy, Sn indicates tin or tin alloy, Ag indicates silver or silver alloy, and Pd indicates palladium or palladium alloy.

### EFFECT OF THE INVENTION

In the semiconductor package and the manufacturing method thereof, the plating layer on the lateral surface of each of the terminals, or each of the terminals and the die pad, projecting from the resin, can be formed without applying plating current directly to the terminals, since this plating layer is formed by the electroless plating. This configuration can prevent oxidation or contamination of the terminals, or copper diffusion.

Particularly, the electroless plating layer comprising any one of Ni, Sn, Ag, Ag/Au, Ni/Au, Ni/Ag, Ni/Pd/Au, and Ni/Pd/Ag has oxidation resistance and good solderability, so that the solder is wet and rises sufficiently during soldering. Therefore, the exposed surface of the terminal is coated not only with the electroless plating layer but also with the solder, when the terminal is assembled into a finished product.

Not only the lateral surface of the terminal, but also the bottom surface of the same is coated with the electroless plating layer, thereby reducing the thickness of the electrolytic plating layer previously formed on the bottom surface of the terminal. This feature reduces material cost.

If the outermost layer of the lateral and bottom surfaces of the terminal is formed by the organic film which does not interfere with the solder joint with the board (i.e., which can be soldered with the board), oxidation and corrosion thereof can be prevented more effectively. In this sense, quality of the solder joint can be improved and the terminal can be protected.

In the manufacturing method of the semiconductor package according to the present invention, any one of Ni, Sn, and Ag can be electroplated to form the second plating layer, since the bottom surface of the lead frame material is etched with the alkali etching solution. Thus, the semiconductor package can be manufactured at a lower cost than the case of plating precious metals such as Au and Pd.

### BRIEF DESCRIPTION OF DRAWINGS

FIG. 1 is a cross-sectional view of a semiconductor package according to one embodiment of the present invention.

FIG. 2 is an enlarged view of a part indicated by an arrow A of FIG. 1.

FIGS. 3 (A) to (G) are process charts of a manufacturing method of the semiconductor package.

FIGS. 4 (a) to (d) are explanatory diagrams of a manufacturing method of a conventional semiconductor package.

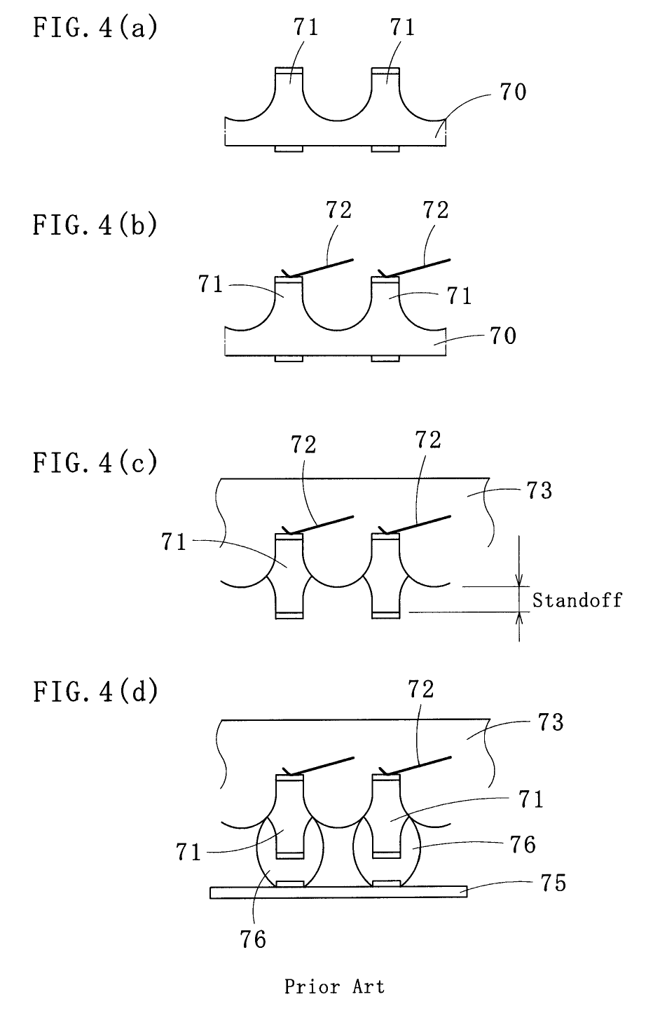

### MODE FOR CARRYING OUT THE INVENTION

Referring to the accompanying drawings, embodiments of the present invention will be explained.

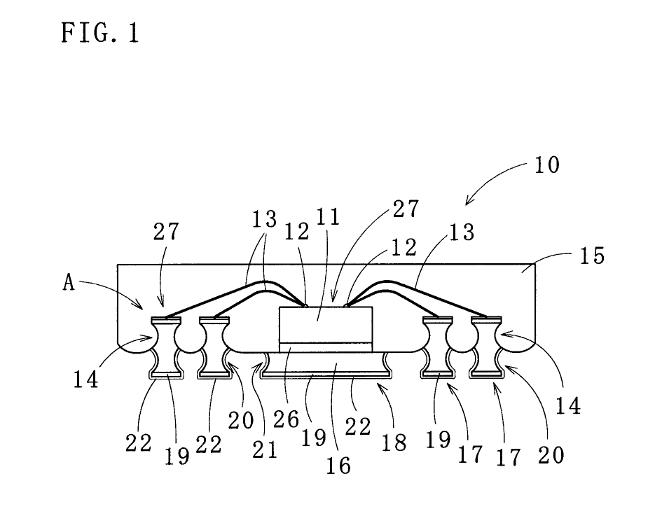

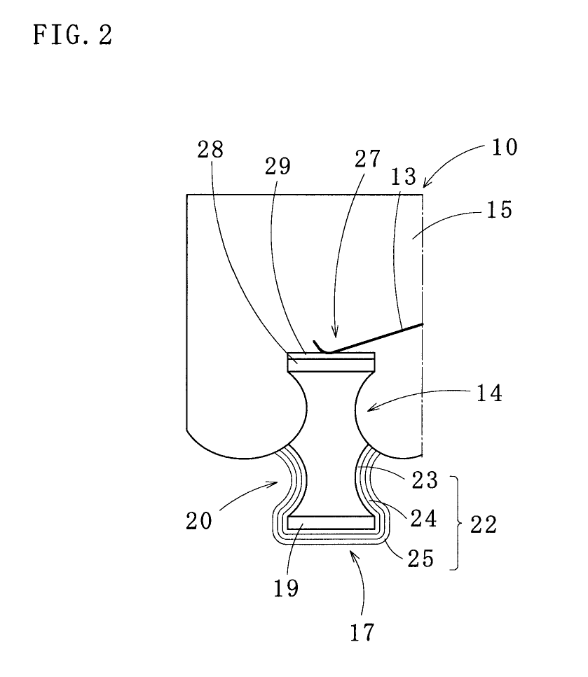

As shown in FIGS. 1 and 2, a semiconductor package 10 according to one embodiment of the present invention includes: a semiconductor device 11 located at the center of the semiconductor package 10; terminals 14 each electrically connected to a contact pad 12 of the semiconductor device 11 via a bonding wire 13; and a resin 15 for sealing a part (upper part) of the terminals 14 and the semiconductor device 11.

Bottom surfaces 17 of the terminals 14 as well as a bottom surface 18 of a central die pad (device mounting area) 16 are each plated with an electrolytic plating (electroplating) layer 19 comprising nickel (Ni plating layer), having a thickness of 0.2 to 1 μm (more preferably 0.4 to 1 μm). Parts (lower parts) of the terminals 14 and the die pad 16 project from the resin 15. Also, lateral surfaces 20 of the terminals 14 as well as a lower surface 21 of the die pad 16 as well as the electrolytic plating layers 19 of the bottom surfaces 17, 18 are each plated with an electroless Ni/Pd/Au plating layer 22.

Preferably, the electroless plating layer 22 includes an Ni plating layer 23 of 0.2 to 1 μm thickness (more preferably 0.2 to 0.5 μm thickness), a Pd plating layer 24 of 0.01 to 0.2 μm thickness (more preferably 0.03 to 0.08 μm thickness), and an uppermost Au plating layer 25 of 0.001 to 0.1 μm thickness (more preferably 0.003 to 0.08 μm thickness).

Upper surfaces (surfaces) 27 of the terminals 14 and the die pad 16 are each electroplated with an Ni plating layer 28 of 0.2 to 1 μm thickness to form a base coat (underlying plate). And, each of the Ni plating layers 28 is further plated with a gold plating layer 29 of 0.1 to 0.5 μm thickness, thereby enabling wire-bonding. A numeral 26 indicates an electrically-conductive adhesive for bondng the semiconductor device 11 on the die pad 16.

Instead of the Ni plating layers 28, 19 respectively formed on the upper surface 27 and the bottom surface 17 of the terminal 14, electrolytic plating layers comprising any one of Ag, Sn, Ni/Au, Ni/Ag, Ni/Pd/Au, and Au may be formed. When the Ag plating layer is formed, Ni may be plated as the base coat.

Instead of the electroless Ni/Pd/Au plating layer 22, the electroless plating layer comprising any one of the followings may be formed: Sn (with a thickness of 4 to 40 μm); Ag (with a thickness of 0.1 to 10 μm); Ag (with a thickness of 0.2 to 1 μm)/Au (with a thickness of 0.1 to 0.5 μm); Ni (with a thickness of 0.2 to 2 μm)/Au (with a thickness of 0.1 to 0.5 μm); Ni (with a thickness of 0.1 to 2 μm)/Ag (with a thickness of 0.1 to 1 μm); Ni (with a thickness of 0.1 to 1 μm)/Pd (with a thickness of 0.01 to 0.2 μm)/Ag (with a thickness of 0.2 to 1 μm); and Ni (with a thickness of 1 to 40 μm).

For example, when the electroless plating layer 22 is formed by electroless Ni plating (Ni—B alloy), the electroless Ni has a face-centered cubic (fcc) crystal structure, functioning as a barrier to copper in a lead frame material. Therefore, copper diffusion, unpreventable only with the electrolytic plating layer 19, can be effectively prevented during solder mounting. Furthermore, the lateral surfaces 20, 21 can be protected, and the solderability of the terminal 14 can be improved.

Now, the present invention is not limited to the above-mentioned values, i.e., plating thicknesses, but encompasses any changes in the values within the scope of the present invention.

Outermost layers of the bottom surfaces 17, 18 and the lateral surface 20, 21 of the terminals 14 and the die pad 16 may be each coated with an organic film solderable with a board. The terminals 14 and the die pad 16 project downwardly from the bottom surface of the semiconductor package 10. For example, a fatty acid surfactant can be used as the organic film.

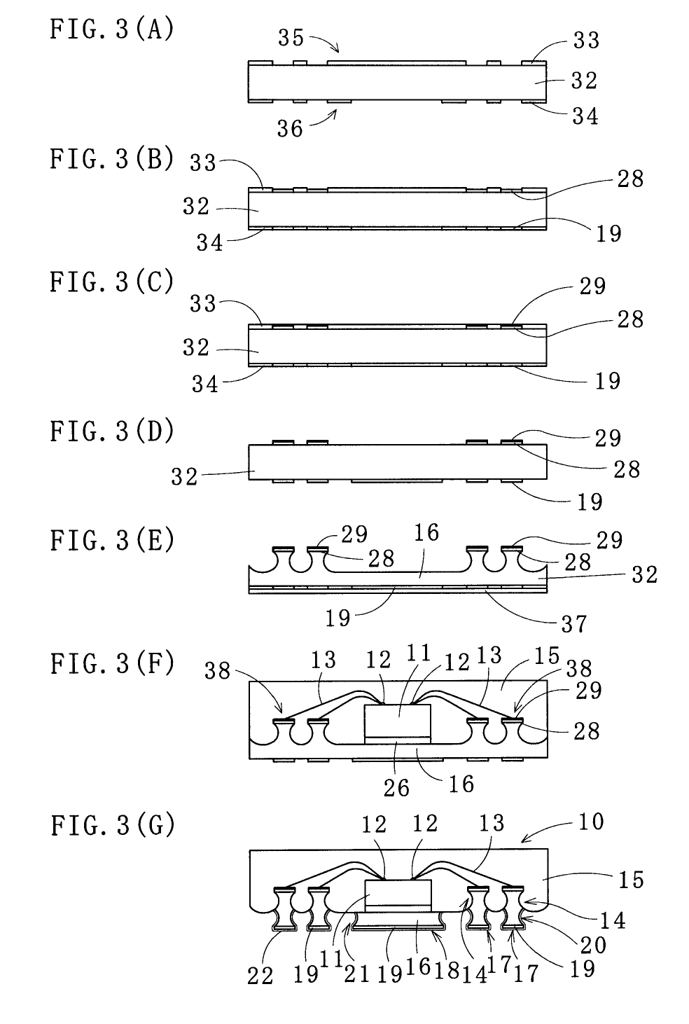

Referring to FIG. 3, one embodiment of a manufacturing method of a semiconductor package according to the present invention will be explained. FIG. 3 shows one semiconductor package 10, however, the present invention is obviously applicable to the case where the semiconductor packages 10 are arranged in a matrix on one large lead frame material and divided into individual packages 10 at the end.

As shown in FIG. 3 (A), a lead frame material 32 made of copper (copper alloy), having a thickness of approximately 0.1 to 1 mm is prepared, and resist films 33, 34 are formed on an upper surface and a lower surface thereof, respectively. Then, a first circuit pattern 35 and a second circuit pattern 36 are formed (printed) through exposure and development.

Next, as shown in FIG. 3 (B), an Ni plating layer 28 with a thickness of 0.2 μm or more but not exceeding 1 μm is electroplated on each opening of the first circuit pattern 35, and an Ni plating layer 19 with a thickness of 0.2-1 μm is electroplated on each opening of the second circuit pattern 36. Then, as shown in FIG. 3 (C), an Au plating layer 29 with a thickness of 0.1 to 0.5 μm is formed by plating Au over the Ni plating layer 28, previously formed on the surface of the lead frame material 32.

As shown in FIG. 3 (D), the resist films 33, 34 are removed. As shown in FIG. 3 (E), the lower surface of the lead frame material 32 is coated with a mask 37. Then, half-etching (first etching) is performed on the upper surface of the lead frame material 32, using the Ni plating layer 28 and the Au plating layer 29 (first plating layers) as the resist films. In this case, an etching solution can be composed primarily of ferric chloride and copper tetramine chloride (one example of alkali etching solutions).

As shown in FIG. 3 (F), the semiconductor device 11 is bonded on the die pad 16 via the electrically-conductive adhesive 26, and then wire-bonding is performed to interconnect the contact pads 12 of the semiconductor device 11 and wire-bonding portions 38, located at upper ends of the terminals 14. After that, the semiconductor device 11, the bonding wires 13, and an upper half of the previously etched lead frame material 32 are sealed with the resin 15, thereby producing an interim product.

After the mask 37 is removed, as shown in FIG. 3 (G), half-etching (second etching) is performed on the bottom surface of the lead frame material 32 with the alkali etching solution, using the Ni plating layers 19 (second plating layers) as the resist films. Through the second etching, the terminals 14 and the die pad 16 are separated from each other.

As shown in FIG. 3 (G), an electroless Ni plating layer of 0.2 to 0.5 μm thickness, an electroless Pd plating layer of 0.03 to 0.08 μm thickness, and an electroless Au plating layer of 0.003 to 0.08 μm thickness are sequentially formed on each of the bottom surfaces 17, 18 and the lateral surfaces 20, 21 of the terminals 14 and the die pad 16, thereby forming electroless plating layers 22 to be protective films (layers).

In short, on the bottom surfaces 17, 18 of the terminals 14 and the die pad 16, the electroless Ni/Pd/Au plating layers 22 are further formed over the electrolytic Ni plating layers 19. These protective layers have a better corrosion resistance than the electroless Ni plating layer only, and cost lower than the comparatively thick electroless Au plating layer. Further, the thin Au plating layer 25 is well compatible with the solder, thereby improving the solderability.

In addition, since the protective layer has a great heat resistance, the semiconductor package can be mounted at high temperatures.

In the semiconductor package described hereinbefore, normally, electric current cannot be applied to the terminals separated from each other after the sealing process. Thus, in this embodiment, the Ni plating layer, the Pd plating layer, and the Au plating layer are formed by the electroless plating to protect the bottom surface and the bare lateral surface of the external terminal, thereby preventing oxidation and contamination of copper as well as a decline in the solderability.

In the manufacturing method of the semiconductor package according to the above embodiment, a plurality of the electroless plating layers may be formed over the electrolytic plating layer comprising Sn or Ag. Since the electroless plating layer can prevent the copper diffusion, any metals with etch resistance can be selected as the electrolytic plating layer. Thus, a degree of freedom in choosing plating metals is increased.

Also, after the formation of the electroless plating layer, the organic film may be formed using antioxidants etc.

Further in this embodiment, the upper portion of the die pad is half-etched, but the present invention is not limited thereto. Alternatively, the half-etching of the die pad in the first etching process may be omitted so as to keep its height as same as that of the terminal. Further alternatively, the semiconductor device may be bonded on the die pad half-etched in the first etching process, and after the sealing process, the die pad may be completely removed in the second etching process.

### INDUSTRIAL APPLICABILITY

In the present invention, for example, the lower surface of the lead frame material is etched with the alkali etching solution, using the Ni plating layer as the resist film. Then, the electroless Ni/Pd/Au plating layers are formed on the lateral surface of the terminal etc. exposed by this etching and the Ni plated bottom surface of the same. As a result, the bottom surface of the external terminal is covered with a coat comprising the electrolytic Ni plating film and the electroless Ni plating film. Therefore, the corrosion of the lateral surface of the terminal can be prevented, and further the semiconductor package can be manufactured in a low cost.

### DESCRIPTION OF NUMERALS

10: semiconductor package, 11: semiconductor device, 12: contact pad, 13: bonding wire, 14: terminal, 15: resin, 16: die pad, 17, 18: bottom surface, 19: electrolytic plating layer (Ni plating layer), 20, 21: lateral surface, 22: electroless plating layer, 23: Ni plating layer, 24: Pd plating layer, 25: Au plating layer, 26: electrically-conductive adhesive, 27: upper surface, 28: Ni plating layer, 29: gold plating layer, 32: lead frame material, 33, 34: resist film, 35: first circuit pattern, 36: second circuit pattern, 37: mask, 38: wire-bonding portion

1-9. (canceled)

10. A manufacturing method of a semiconductor package comprising:
a first step of forming a first circuit pattern on an upper surface of a lead frame material made of copper or copper alloy, the first circuit pattern forming terminals, or terminals and a die pad, and a second circuit pattern on a lower surface of the lead frame material, the second circuit pattern forming the terminals and the die pad;
a second step of forming a first plating layer and a second plating layer respectively on the upper surface and the lower surface of the lead frame material;
a third step of half-etching the lead frame material with an alkali etching solution from the upper surface using the first plating layer as a resist film;
a fourth step of mounting a semiconductor device on the die pad in the upper surface, bonding wires, and then sealing the device with a resin to fabricate an interim product; and
a fifth step of half-etching the interim product with an alkali etching solution using the second plating layer as a resist film, thereby separating the terminals from each other, wherein
the first plating layer in the second step is formed by an electroplating layer of Ni/Au or Ni/Pd/Au; and
the second plating layer in the second step is formed by an electroplating layer of Sn, Ni/Au or Ni/Pd/Au.

11. The manufacturing method as defined in claim 10, wherein
the fifth step is followed by a sixth step of forming at least one electroless plating layer on each of the lateral and bottom surfaces of the terminals and the die pad, projecting from the resin.

12. The manufacturing method as defined in claim 11, wherein
the electroless plating layer is formed by a layer of Ni, Sn, Ag, Ag/Au, Ni/Au, Ni/Ag, Ni/Pd/Au, or Ni/Pd/Ag.

13. The manufacturing method as defined in claim 11, wherein
uppermost layers of the terminals and the die pad, projecting from the resin, are each coated with an organic film which does not interfere with solder joint with a board.

14. The manufacturing method as defined in claim 12, wherein
uppermost layers of the terminals and the die pad, projecting from the resin, are each coated with an organic film which does not interfere with solder joint with a board.
